(19) United States
(12) Patent Application Publication
(10) Pub. No.: US 2025/0298485 A1
(43) Pub. Date: Sep. 25, 2025

(54) SENSOR DEVICE

(71) Applicant: ALPS ALPINE CO., LTD., Tokyo (JP)

(72) Inventors: Takashi SASAKI, Miyagi (JP); Ken KAMAGATA, Miyagi (JP); Keito OSAKI, Miyagi (JP)

(21) Appl. No.: 19/045,001

(22) Filed: Feb. 4, 2025

(30) Foreign Application Priority Data
Mar. 25, 2024 (JP) 2024-047923

(51) Int. Cl. G06F 3/044; B60R 16/03; B62D 1/06

(52) U.S. Cl. CPC G06F 3/044; B60R 16/03; B62D 1/065

(57) ABSTRACT

To provide a sensor device having low power consumption, sensor device includes: sensor electrode operable as heating element; electrostatic detection circuit for detecting capacitance between sensor electrode and an object; high-side switch connected to power source for supplying power for heating to sensor electrode; decoupling switch; low-side switch; voltage supply circuit for supplying voltage to a node between decoupling switch and one end of sensor electrode such that voltage of the node becomes higher than voltage of reference potential point; electronic element composed of resistor or switch provided between connection point of high-side switch and decoupling switch and reference potential point; and controller for controlling high-side switch, decoupling switch, and low-side switch, wherein the source of the high-side switch and the source of the decoupling switch are connected to the connection point and are connected to the reference potential point via the electronic element.

### CROSS-REFERENCE TO RELATED APPLICATION

The present application claims priority under 35 U.S.C. § 119 to Japanese Patent Application No. 2024-047923, filed Mar. 25, 2024, the contents of which are incorporated herein by reference in their entireties.

### BACKGROUND OF THE INVENTION

### Field of the Invention

This disclosure relates to a sensor device.

### Description of the Related Art

Conventionally, there has been a sensor device that includes: an electrode body including a heating element serving as a sensor electrode; a detection device for detecting the capacitance of the sensor electrode; a high-side switch provided between a heating power source and the heating element; a low-side switch provided between the heating element and a reference potential point; a gate controller for opening the high-side switch and the low-side switch in a detection mode; and a decoupling circuit including a decoupling MOSFET connected between the high-side switch and the heating element. The gate controller sets the decoupling MOSFET in an electrically conductive state in a heating mode, and opens the decoupling MOSFET in the detection mode. In the detection mode, the decoupling circuit supplies a third potential to a first node connected between the high-side switch and the decoupling MOSFET. A potential different from the third potential is supplied to a node between the low-side switch and the heating element. The high-side switch is an N-channel MOSFET, the low-side switch is a P-channel MOSFET, and the decoupling circuit is an N-channel MOSFET (see, for example, United States Patent Application Publication No. 2023/0046256).

### SUMMARY OF THE INVENTION

A P-channel MOSFET has a higher ON resistance and a higher power consumption than those of an N-channel MOSFET.

Therefore, it is an object of the present disclosure to provide a sensor device having a low power consumption.

A sensor device according to an embodiment of the present disclosure includes: a sensor electrode operable as a heating element; an electrostatic detection circuit configured to detect a capacitance between the sensor electrode and an object; a high-side switch connected to a power source for supplying power for heating to the sensor electrode; a decoupling switch provided between the high-side switch and one end of the sensor electrode; a low-side switch provided between the other end of the sensor electrode and a reference potential point; a voltage supply circuit configured to supply a voltage to a node between the decoupling switch and the one end of the sensor electrode such that the voltage of the node becomes higher than a voltage of the reference potential point; an electronic element composed of a resistor or a switch provided between a connection point between the high-side switch and the decoupling switch and the reference potential point; and a controller configured to control the high-side switch, the decoupling switch, and the low-side switch, wherein a voltage of the power source is higher than the voltage of the reference potential point, the high-side switch, the decoupling switch, and the low-side switch are N-channel MOSFETs, a drain of the high-side switch is connected to the power source, a drain of the decoupling switch is connected to the node, a drain of the low-side switch is connected to the other end of the sensor electrode, a source of the low-side switch is connected to the reference potential point, and a source of the high-side switch and a source of the decoupling switch are connected to the connection point and are connected to the reference potential point via the electronic element.

A sensor device having a low power consumption can be provided.

### BRIEF DESCRIPTION OF THE DRAWINGS

FIG. 1 is a view schematically showing a steering wheel mounted with a sensor device of the embodiment;

FIG. 2 is a diagram showing an example of the circuit configuration of a sensor device of the embodiment;

FIG. 3A is a diagram showing an example of parasitic capacitances Coss between a source and a drain of a high-side MOSFET, a low-side MOSFET, and a decoupling MOSFET in a non-heating mode;

FIG. 3B is a diagram showing an example of parasitic capacitances Coss between a source and a drain of a high-side MOSFET, a low-side MOSFET, and a decoupling MOSFET in a non-heating mode;

FIG. 4 is a diagram showing an example of electrical characteristics of an N-channel MOSFET; and

FIG. 5 is a diagram showing an example of the circuit configuration of a sensor device according to a modified example of an embodiment.

### DETAILED DESCRIPTION OF THE DISCLOSURE

Embodiments to which a sensor device of the present disclosure is applied will be described below.

### EMBODIMENT

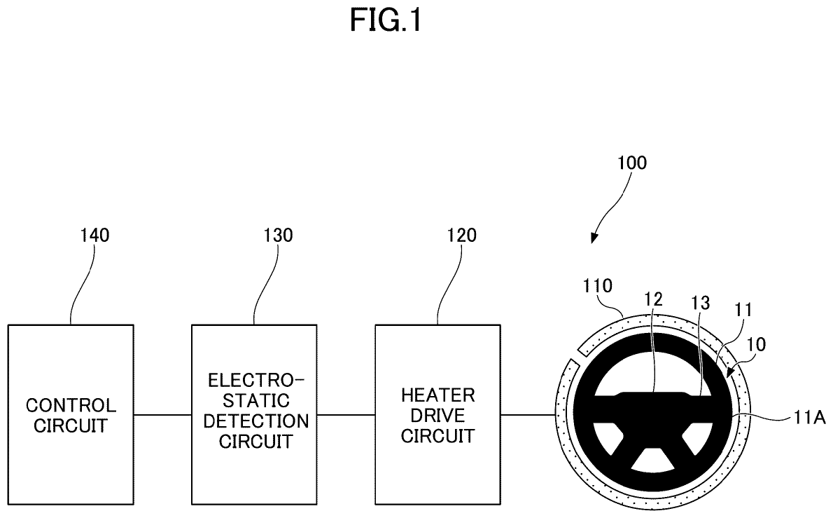

FIG. 1 is a view schematically showing a steering wheel 10 mounted with a sensor device 100 of the embodiment. The sensor device 100 includes a sensor electrode 110, a heater drive circuit 120, an electrostatic detection circuit 130, and a control circuit 140. The control circuit 140 is an example of a controller.

The steering wheel 10 is mounted on a vehicle, and the sensor electrode 110 of the sensor device 100 is mounted on the inner side of the skin of a rim 11. The sensor electrode 110 can operate as a heating element. The sensor device 100 determines whether or not a hand of a driver is in contact with the rim 11 of the steering wheel 10. The sensor device 100 warms the steering wheel 10 by supplying power for heating to the sensor electrode 110. That is, the sensor device 100 has both the functions as a Hands On Detection (HOD) and as a steering wheel heater. A hand is an example of an object. The rim 11 of the steering wheel 10 is an example of a fixing part to which the sensor electrode 110 is fixed. The skin 11A of the rim 11 is an example of a contact part which the detection object can contact.

Hereinafter, the driver of a vehicle is referred to as the operator of the sensor device 100. The operator's touching the rim 11 of the steering wheel 10 mounted with the sensor electrode 110 is referred to as an operator's operation.

The steering wheel 10 has the rim 11, a hub 12, and a spoke 13. Those that are shown as the rim 11, the hub 12, and the spoke 13 in FIG. 1 are the core metal parts of the rim 11, the hub 12, and the spoke 13. In FIG. 1, in order to show the sensor electrode 110, the sensor electrode 110 is shown apart from the skin 11A of the rim 11. In FIG. 1, a cover covering the hub 12 and the spoke 13 is omitted.

A ground terminal of the steering wheel 10 is electrically connected to the core metal provided on the whole circumference of the rim 11 of the steering wheel 10 over one circumference. With the core metal connected to a ground terminal of the heater drive circuit 120, the electrostatic detection circuit 130, and the control circuit 140 via a connector (not shown), the ground potential of the heater drive circuit 120, the electrostatic detection circuit 130, and the control circuit 140 is equal to the ground potential of the steering wheel 10.

### <Schematic Structure of Sensor Device 100>

The sensor device 100 includes the sensor electrode 110, the heater drive circuit 120, the electrostatic detection circuit 130, and the control circuit 140. The control circuit 140 may be an Electronic Control Unit (ECU). FIG. 1 shows a simplified connection relationship between the sensor electrode 110, the heater drive circuit 120, the electrostatic detection circuit 130, and the control circuit 140. The control circuit 140 is also connected to the heater drive circuit 120 via a cable, a connector, or the like not shown.

The sensor device 100 has two modes: a heating mode of supplying power for heating to the sensor electrode 110 from the power source of a vehicle, and a non-heating mode of not supplying the power for heating. The control circuit 140 switches the mode of the sensor device 100 in a time division manner. That is, there is a time for the control circuit 140 to set the sensor device 100 in the heating mode and a time for the control circuit 140 to set the sensor device 100 in the non-heating mode.

### <Sensor Electrode 110>

The sensor electrode 110 is provided along the whole circumference of the rim 11 of the steering wheel 10 in a state of being insulated from the core metal provided along the whole circumference of the rim 11 of the steering wheel 10. The sensor electrode 110 is connected to the heater drive circuit 120, the electrostatic detection circuit 130, and the control circuit 140 via a signal line or the like. The sensor electrode 110 is a thin sheet-like belt-like electrode provided along the whole circumference of the rim 11, and can be produced by, for example, applying a conductive material such as silver paste or the like to the surface of a resin film.

### <Heater Drive Circuit 120>

The heater drive circuit 120 is connected to the sensor electrode 110 and supplies power for heating to the sensor electrode 110 from the power source of a vehicle in the heating mode.

### <Electrostatic Detection Circuit 130>

The electrostatic detection circuit 130 is connected to the sensor electrode 110 and detects the capacitance between the sensor electrode 110 and the operator's hand.

### <Control Circuit 140>

The control circuit 140 is implemented by a computer including a Central Processing Unit (CPU), a Random Access Memory (RAM), a Read Only Memory (ROM), an input/output interface, an internal bus, and the like. The control circuit 140 switches the mode of the sensor device 100 between the heating mode and the non-heating mode. In the heating mode, the control circuit 140 heats the sensor electrode 110 and warms the rim 11 of the steering wheel 10. In the non-heating mode, the control circuit 140 determines whether or not a hand is touching the rim 11 of the steering wheel 10 based on an output from the electrostatic detection circuit 130. Details of the control performed by the control circuit 140 in the non-heating mode and the heating mode will be described later.

### <Circuit Configuration of Sensor Device 100>

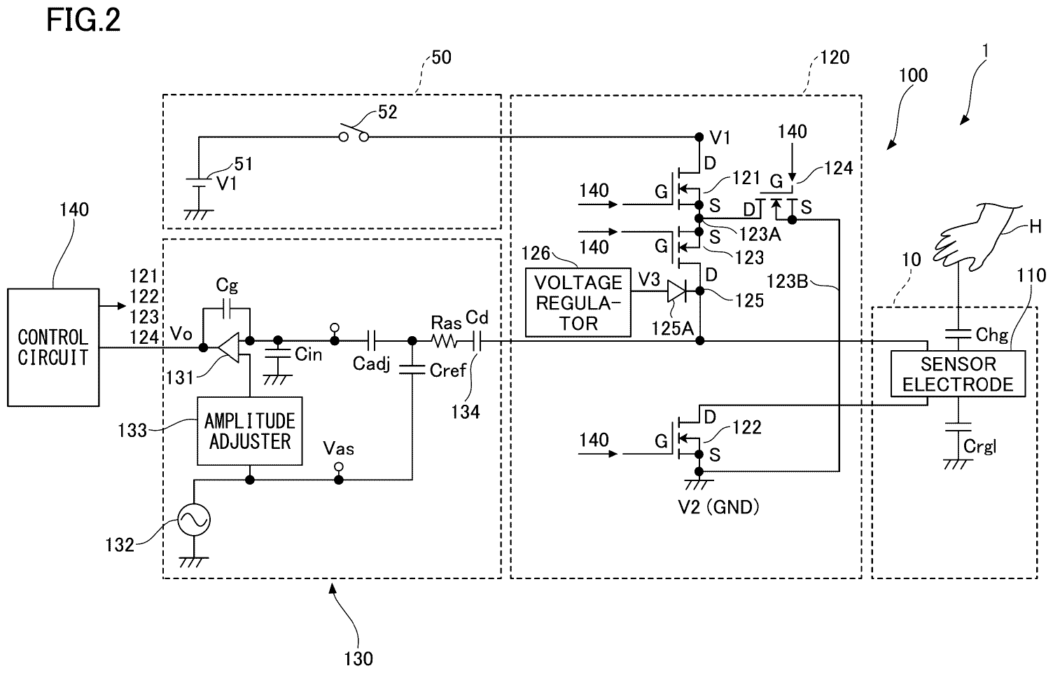

FIG. 2 is a diagram showing an example of the circuit configuration of the sensor device 100. FIG. 2 also shows the power source circuit 50 of a vehicle 1 on which the sensor device 100 is mounted. The power source circuit 50 includes a power source 51 and a relay 52. As an example, the power source 51 is a battery of the vehicle 1. Although descriptions will be based on the power source 51 of FIG. 2 being a battery, the power source 51 may include a power generator, a regeneration device, or the like of the vehicle 1 in addition to the battery. The output voltage of the power source 51 is V1.

The power source circuit 50 includes the power source 51 and the relay 52. The relay 52 is inserted in series in a power supply path between the power source 51 and the heater drive circuit 120. As an example, opening or closing of the relay 52 is controlled by a body ECU (not shown).

### <Sensor Electrode 110>

The sensor electrode 110 is provided on the steering wheel 10 and connected to the heater drive circuit 120. More specifically, as shown in FIG. 1, the sensor electrode 110 is a conductor having ends on both sides, and one end is connected to a node 125. The other end of the sensor electrode 110 is connected to the drain of a low-side MOSFET 122.

A parasitic capacitance between the sensor electrode 110 and a ground potential point is Crgl, and a capacitance between the sensor electrode 110 and a hand H is Chg. The capacitance Chg varies greatly depending on whether the hand H is in contact with the sensor electrode 110.

### <Heater Drive Circuit 120>

The heater drive circuit 120 includes a high-side MOSFET 121, a low-side MOSFET 122, a decoupling MOSFET 123, a switching MOSFET 124, the node 125, and a voltage regulator 126. The high-side MOSFET 121 is an example of a high-side switch, the low-side MOSFET 122 is an example of a low-side switch, and the decoupling MOSFET 123 is an example of a decoupling switch. The switching MOSFET 124 is an example of an electronic element. The voltage regulator 126 is an example of a voltage supply circuit.

The high-side MOSFET 121, the low-side MOSFET 122, the decoupling MOSFET 123, and the switching MOSFET 124 are composed of N-channel MOSFETs. Since N-channel MOSFETs have a ON-resistance lower than that of P-channel MOSFETs, there is an advantage that power consumption saving is easier.

The drain of the high-side MOSFET 121 is connected to the power source 51 via the relay 52, the source thereof is connected to the source of the decoupling MOSFET 123, and the gate thereof is connected to the control circuit 140. The drain of the high-side MOSFET 121 is supplied with a voltage V1 of the power source 51. Therefore, the drain of the high-side MOSFET 121 is denoted as V1. The high-side MOSFET 121 is driven by a PWM-type gate drive signal supplied to the gate from the control circuit 140.

The drain of the low-side MOSFET 122 is connected to the sensor electrode 110, the source thereof is connected to the reference potential point (V2), and the gate thereof is connected to the control circuit 140. The reference potential point is a ground potential point, and the voltage of the reference potential point is V2 (GND). The low-side MOSFET 122 is provided between the sensor electrode 110 and the reference potential point, and is driven by a PWM-type gate drive signal supplied to the gate from the control circuit 140.

The decoupling MOSFET 123 is provided between the high-side MOSFET 121 and the sensor electrode 110. The drain of the decoupling MOSFET 123 is connected to the node 125, the source thereof is connected to the source of the high-side MOSFET 121, and the gate thereof is connected to the control circuit 140. The point at which the source of the decoupling MOSFET 123 and the source of the high-side MOSFET 121 are connected is a connection point 123A. The connection point 123A is a connection point between the high-side MOSFET 121 and the decoupling MOSFET 123. The decoupling MOSFET 123 is driven by a PWM-type gate drive signal supplied to the gate from the control circuit 140.

In the heating mode, the control circuit 140 sets the gate voltages of the high-side MOSFET 121, the decoupling MOSFET 123, and the low-side MOSFET 122 to the H (High) level, to set the high-side MOSFET 121, the decoupling MOSFET 123, and the low-side MOSFET 122 in an electrically conductive state. When changing the mode to the non-heating mode, the control circuit 140 first sets the gate voltages of the high-side MOSFET 121 and the decoupling MOSFET 123 to the L (Low) level, to set the high-side MOSFET 121 and the decoupling MOSFET 123 in an open state (OFF). Next, the control circuit 140 sets the gate voltage of the low-side MOSFET 122 to the (Low) level, to set the low-side MOSFET 122 in an open state (OFF). When changing the mode to the non-heating mode, a time for which the high-side MOSFET 121 and the decoupling MOSFET 123 are in an open state and the low-side MOSFET is in an electrically conductive state is provided, to thereby set the potential of the sensor electrode 110 in the non-heating mode to the reference potential (GND).

The gate driving signals for driving the high-side MOSFET 121, the low-side MOSFET 122, and the decoupling MOSFET 123 are not limited to the PWM type. When not heating the sensor electrode 110, each gate driving signal may be maintained at the L level. The body ECU may adjust the temperature of the sensor electrode 110 (heating element) by changing the voltage V1. In this case, the times for the control circuit 140 to set the gate driving signal to the H level and to set the gate driving signal to the L level may be fixed.

The switching MOSFET 124 is connected to a line 123B connecting the connection point 123A and the reference potential point. The drain of the switching MOSFET 124 is connected to the connection point 123A, the source thereof is connected to the reference potential point, and the gate thereof is connected to the control circuit 140. The switching MOSFET 124 is driven by a gate drive signal supplied to the gate from the control circuit 140. The line 123B is a line connecting the connection point 123A and the reference potential point, and is connected to the source of the low-side MOSFET 122 on the reference potential point side. The switching MOSFET 124 is always kept in an open state (OFF) in the heating mode, and is always kept in an electrically conductive state (ON) in the non-heating mode.

The node 125 is a node between the drain of the decoupling MOSFET 123 and the sensor electrode 110. The node 125 is connected to the voltage regulator 126, and is supplied with a voltage V3 that is output from the voltage regulator 126. The voltage of the node 125 is higher than the voltage of the reference potential point V2. The node 125 is located between the drain of the decoupling MOSFET 123, the sensor electrode 110, and a capacitor 134 of the electrostatic detection circuit 130.

The voltage regulator 126 is connected to the node 125, and outputs the voltage V3 to the node 125. The voltage regulator 126 converts the voltage V1 supplied from the power source 51 to the voltage V3. The voltage V3 output from the voltage regulator 126 is lower than the voltage V1 of the power source 51. A voltage-dividing resistor may be used in place of the voltage regulator 126 to convert the voltage V1 to the voltage V3. In order to prevent a backflow to the voltage regulator 126, a diode 125A may be provided between the voltage regulator 126 and the node 125. By providing a switch between the voltage regulator 126 and the node 125 and switching OFF the switch in the heating mode, it is possible to make the voltage V3 output from the voltage regulator 126 higher than the voltage V1 of the power source 51.

### <Electrostatic Detection Circuit 130>

The electrostatic detection circuit 130 includes a charge amplifier 131, an Alternating-Current (AC) signal source 132, an amplitude adjuster 133, and the capacitor 134. The electrostatic detection circuit 130 detects capacitance by the self-capacitance method of the sensor electrode 110. The AC signal source 132 is an example of a sinusoidal signal source. Since the electrostatic detection circuit 130 detects capacitance by the self-capacitance method, the sensitivity of capacitance at the sensor electrode 110 can be improved. The electrostatic detection circuit 130 may detect capacitance by the self-capacitance method of the sensor electrode 110 only in the non-heating mode.

The charge amplifier 131 has a non-inverting input terminal (+) that is connected to the output terminal of the amplitude adjuster 133, an inverting input terminal (−) that is connected to the sensor electrode 110 via the capacitor 134, and an output terminal that is connected to the control circuit 140. The output voltage of the output terminal of the charge amplifier 131 is V₀. The charge amplifier 131 is a differential amplifier that amplifies the difference between an input into the non-inverting input terminal (+) and an input into the inverting input terminal (−) and outputs it as an output signal.

The AC signal source 132 is connected to the amplitude adjuster 133 and to the sensor electrode 110 via the capacitor 134. The AC signal source 132 outputs an AC signal (sinusoidal signal) for driving the sensor electrode 110. The AC signal source 132 may stop outputting the AC signal in the heating mode.

The amplitude adjuster 133 performs amplitude adjustment such that the difference between the inverting input terminal (−) and the non-inverting input terminal (+) is eliminated and the output voltage V₀ of the charge amplifier 131 becomes a minimum in a state in which there is no hand H, which is an object, that is close to the sensor electrode 110 (in a state in which the capacitance Chg is 0).

The capacitor 134 has a terminal (left terminal in FIG. 2) that is connected to the inverting input terminal (−) of the charge amplifier 131 and to the amplitude adjuster 133, and a terminal that is connected to the sensor electrode 110. That is, the capacitor 134 is inserted in series between the inverting input terminal (−) of the charge amplifier 131 and the sensor electrode 110. The capacitor 134 is an example of a capacitor for Direct-Current (DC) separation provided to cut off a DC component between the heater drive circuit 120 and the electrostatic detection circuit 130. The capacitance of the capacitor 134 is Cd.

### <Control Circuit 140>

The control circuit 140 outputs a gate drive signal to the gates of the high-side MOSFET 121, the low-side MOSFET 122, the decoupling MOSFET 123, and the switching MOSFET 124 to control switching between an electrically conductive state and an open state.

In the non-heating mode, the control circuit 140 outputs a gate drive signal having a L (Low) level to the gates of the high-side MOSFET 121, the low-side MOSFET 122, and the decoupling MOSFET 123, and outputs a gate drive signal having an H (High) level to the gate of the switching MOSFET 124.

Thus, in the non-heating mode, the high-side MOSFET 121, the low-side MOSFET 122, and the decoupling MOSFET 123 enter an open state (off). The high-side MOSFET 121, the low-side MOSFET 122, and the decoupling MOSFET 123 entering an open state (off) is equivalent to the sensor electrode 110 becoming free of the power source circuit 50.

The control circuit 140 converts a signal output from the charge amplifier 131 into a digital signal, and demodulates it using a demodulation signal having the same frequency as that of the AC signal. Based on the demodulated output, the control circuit 140 determines whether or not the hand H is touching the sensor electrode 110. The control circuit 140 may determine whether or not the hand H is touching the sensor electrode 110 only in the non-heating state.

In the heating mode, the control circuit 140 outputs PWM-type gate drive signals having an H level and synchronized with each other at the same frequency to the gates of the high-side MOSFET 121, the low-side MOSFET 122, and the decoupling MOSFET 123, and outputs a L-level gate drive signal to the gate of the switching MOSFET 124. Thus, the high-side MOSFET 121, the low-side MOSFET 122, and the decoupling MOSFET 123 enter an electrically conductive state (ON), and the switching MOSFET 124 enters an open state (OFF). Therefore, a flow occurs from the power source 51 to the reference potential point through the high-side MOSFET 121, the decoupling MOSFET 123, the sensor electrode 110, and the low-side MOSFET 122. As a result, the sensor electrode 110 generates heat and functions as a heater.

The control circuit 140 may determine the duty ratio of the PWM-type gate drive signal (PWM signal) by feedback control based on the target temperature of the heater of the steering wheel 10, the current temperature of the heater of the steering wheel 10, and the like. The temperature of the heater of the steering wheel 10 may be measured by a temperature sensor provided on the steering wheel 10.

Instead of the switching MOSFET 124, a high-resistance resistor may be provided on the line 123B. With a high-resistance resistor provided on the line 123B instead of the switching MOSFET 124, in the non-heating mode, the connection point 123A can be maintained at the reference potential, whereas in the heating mode, a current can flow through the path from the high-side MOSFET 121 to the decoupling MOSFET 123, the sensor electrode 110, and the low-side MOSFET 122 and cause the sensor electrode 110 to generate heat since almost no current flows through the high-resistance resistor in the heating mode. However, in order to save the power to be consumed by the resistor in the heating mode, the resistance value is set to be higher than 1 kΩ. In addition, in order to shorten the time taken for the voltage of the connection point 123A to become V2 when the mode is switched to the non-heating mode, the resistance value is set to be lower than 100 kΩ.

### <Parasitic Capacitances of High-Side MOSFET 121, Low-Side MOSFET 122, and Decoupling MOSFET 123>

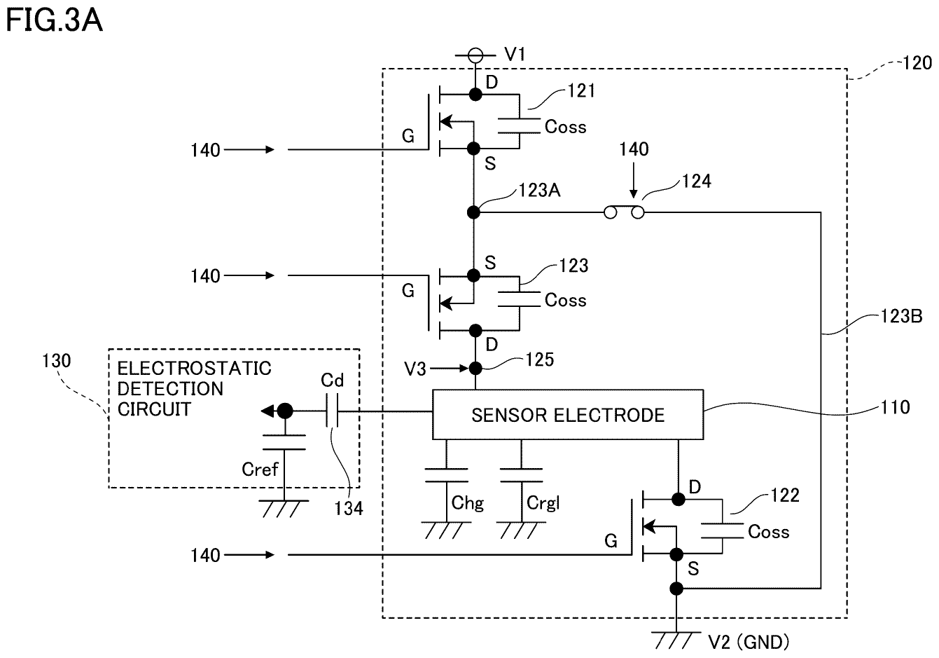

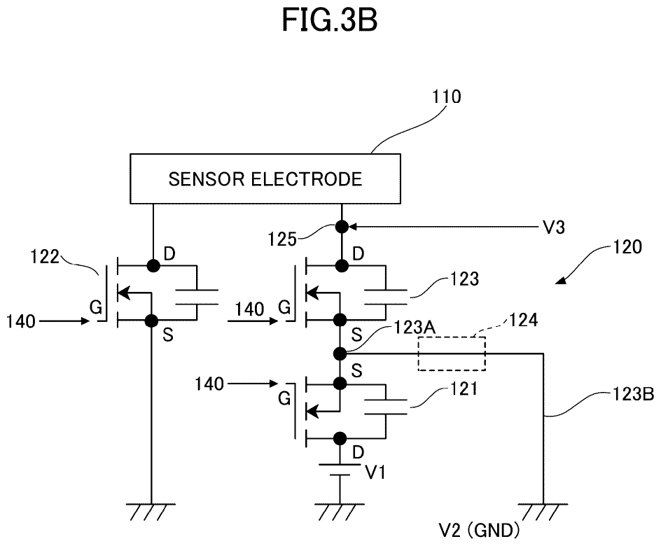

FIG. 3A shows an example of parasitic capacitances Coss between the drain and the source of the high-side MOSFET 121, the low-side MOSFET 122, and the decoupling MOSFET 123 in the non-heating mode. The high-side MOSFET 121, the low-side MOSFET 122, and the decoupling MOSFET 123 are, for example, of the same type of N-channel MOSFET, and have the same parasitic capacitance Coss vs. drain-source voltage VDS characteristic.

FIG. 3A shows the sensor electrode 110, the high-side MOSFET 121, the low-side MOSFET 122, the decoupling MOSFET 123, the node 125, the capacitor 134 of the electrostatic detection circuit 130, and the like among the components shown in FIG. 2. In FIG. 3A, the switching MOSFET 124, which is set in an electrically conductive state in the non-heating mode, is shown as a switch in a closed state, the power source 51 is shown as a power source V1, and the other components are omitted.

The parasitic capacitances Coss exist between the drain and the source of the high-side MOSFET 121, the low-side MOSFET 122, and the decoupling MOSFET 123. A MOSFET has an electrical characteristic in which the parasitic capacitance Coss between the drain and the source changes with respect to the voltage across the drain and source. In general, the higher the voltage across the drain and the source, the less the parasitic capacitance Coss. Therefore, in the N-channel MOSFET, the higher the voltage of the drain with respect to the source, the less the parasitic capacitance Coss.

The parasitic capacitance Coss affects the detection sensitivity when detecting the capacitance of the sensor electrode 110. That is, in the sensor device 100, in the non-heating mode for detecting the capacitance of the sensor electrode 110, it is preferable to reduce the parasitic capacitances Coss of the high-side MOSFET 121, the low-side MOSFET 122, and the decoupling MOSFET 123 to some extent in order to obtain a good detection sensitivity by minimizing decrease in the detection sensitivity.

Here, in the non-heating mode, as shown in FIG. 3A, the switching MOSFET 124 is in an electrically conducting state (ON), and all of the high-side MOSFET 121, the low-side MOSFET 122, and the decoupling MOSFET 123 are in an open state (OFF). The decoupling MOSFET 123 is connected between the power source V1 and the reference potential point in a drain-source direction opposite to that of the high-side MOSFET 121 and the low-side MOSFET 122.

FIG. 3B shows the configuration shown in FIG. 3A in a further modified form. FIG. 3B shows the high-side MOSFET 121 and the decoupling MOSFET 123 under the sensor electrode 110 in a turned-around manner, and shows the power source V1 by the DC power source symbol. In FIG. 3B, the switching MOSFET 124 provided on the line 123B is omitted in order to show a state in which the switching MOSFET 124 is in an electrically conductive state (ON) in the non-heating mode as in FIG. 3A, and only the position of the switching MOSFET 124 is indicated by a dashed square.

In the sensor device 100, the high-side MOSFET 121, the low-side MOSFET 122, and the decoupling MOSFET 123 are all N-channel types. In order to realize this configuration, the drain of the decoupling MOSFET 123 is connected on the reference potential point side between the power source V1 and the reference potential point, and the source thereof is connected on the power source V1 side. In order to make the decoupling MOSFET 123 connected in this way operable, the voltage regulator 126 applies the voltage V3 to the drain of the decoupling MOSFET 123.

In the non-heating mode, the high-side MOSFET 121, the low-side MOSFET 122, and the decoupling MOSFET 123 are all set to an open state (off). In this state, when viewed from the connection point 123A, the high-side MOSFET 121 is connected in parallel with the line 123B connected to the reference potential point, which is equivalent to a state in which the high-side MOSFET 121 does not exist. Therefore, the parasitic capacitance Coss between the drain and the source of the high-side MOSFET 121 does not affect the sensor electrode 110.

Therefore, in the non-heating mode, the parasitic capacitance Crgl of the sensor electrode 110 is the total of the parasitic capacitance Coss between the drain and the source of the low-side MOSFET 122 and the parasitic capacitance Coss between the drain and the source of the decoupling MOSFET 123. Moreover, since the parasitic capacitance Crgl of the sensor electrode 110 is not affected by the parasitic capacitance Coss between the drain and the source of the high-side MOSFET 121, it is not affected by the parasitic capacitance Coss between the drain and the source of the high-side MOSFET 121 that is subject to variation of the voltage of the power source V1, either.

Since the low-side MOSFET 122 and the decoupling MOSFET 123 are connected via the sensor electrode 110, the drain-source voltages of the low-side MOSFET 122 and the decoupling MOSFET 123 in the non-heating mode are approximately equal to the voltage V3.

### <Example of Electrical Characteristic of MOSFET>

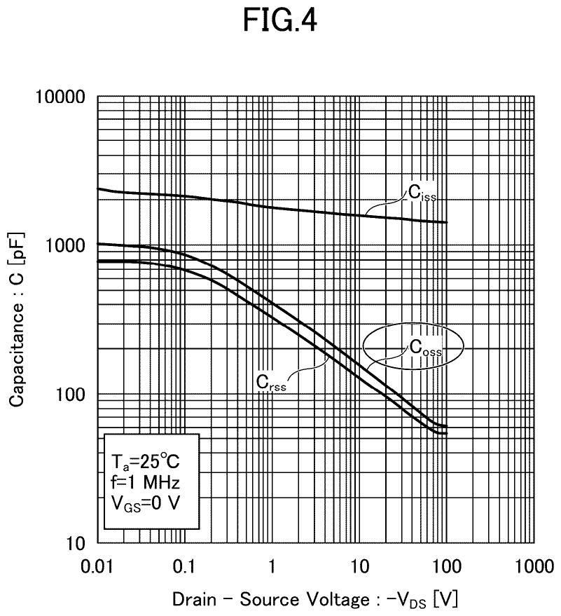

FIG. 4 shows an example of the electrical characteristic of an N-channel MOSFET. In FIG. 4, the horizontal axis represents the voltage VDS (V) of the drain with respect to the source of an N-channel MOSFET. In FIG. 4, the vertical axis represents the parasitic capacitance Coss (pF). In FIG. 4, the region where the voltage on the horizontal axis is approximately 1 V or higher is a region where the parasitic capacitance Coss sharply decreases.

In the sensor device 100, the voltages VDS of the low-side MOSFET 122 and the decoupling MOSFET 123 in the non-heating mode are approximately equal to the voltage V3. Therefore, by setting the voltage V3 to approximately 1 V or higher, it is possible to reduce the parasitic capacitances Coss of both of the low-side MOSFET 122 and the decoupling MOSFET 123.

As a result, the parasitic capacitance Crgl of the sensor electrode 110 can be reduced. Moreover, the parasitic capacitance Crgl of the sensor electrode 110 can be prevented from being affected by variation of the voltage of the power source V1.

For example, when the voltage V3 is set to approximately 3 V, the parasitic capacitances Coss of the low-side MOSFET 122 and the decoupling MOSFET 123 become approximately 200 pF, which is a very small value. The sum of the two parasitic capacitances Coss is approximately 400 pF. Since this total parasitic capacitance is the parasitic capacitance Crgl between the sensor electrode 110 and the ground potential point, the parasitic capacitance Crgl between the sensor electrode 110 and the ground potential point is very small.

In the sensor device 100 of the embodiment, the parasitic capacitance Crgl of the sensor electrode 110 in the non-heating mode becomes very small, making it possible to obtain a good detection sensitivity by minimizing decrease in the detection sensitivity when detecting the capacitance of the sensor electrode 110. In the sensor device 100, the high-side MOSFET 121, the low-side MOSFET 122, and the decoupling MOSFET 123 are all N-channel MOSFETs. N-channel MOSFETs consume less power than do P-channel MOSFETs.

Therefore, in the heating mode in which all of the high-side MOSFET 121, the low-side MOSFET 122, and the decoupling MOSFET 123 are in an electrically conductive state, the power consumption is low.

### Effect

The sensor device 100 includes: the sensor electrode 110 operable as a heating element; the electrostatic detection circuit 130 for detecting the capacitance between the sensor electrode 110 and an object; the high-side MOSFET 121 connected to the power source 51 for supplying power for heating to the sensor electrode 110; the decoupling MOSFET 123 provided between the high-side MOSFET 121 and one end of the sensor electrode 110; the low-side MOSFET 122 provided between the other end of the sensor electrode 110 and the reference potential point; the voltage regulator 126 for supplying a voltage to the node 125 between the decoupling MOSFET 123 and the one end of the sensor electrode 110 such that the voltage of the node 125 becomes higher than the voltage of the reference potential point; the switching MOSFET 124 composed of a resistor or a switch provided between the connection point 123A between the high-side MOSFET 121 and the decoupling MOSFET 123, and the reference potential point; and the control circuit 140 for controlling the high-side MOSFET 121, the decoupling MOSFET 123, and the low-side MOSFET 122, wherein the voltage V1 of the power source 51 is higher than the voltage V2 of the reference potential point, wherein the high-side MOSFET 121, the decoupling MOSFET 123, and the low-side MOSFET 122 are N-channel MOSFETs, and wherein the drain of the high-side MOSFET 121 is connected to the power source 51, the drain of the decoupling MOSFET 123 is connected to the node 125, the drain of the low-side MOSFET 122 is connected to the other end of the sensor electrode 110, the source of the low-side MOSFET 122 is connected to the reference potential point, and the source of the high-side MOSFET 121 and the source of the decoupling MOSFET 123 are connected to the connection point 123A and connected to the reference potential point via the switching MOSFET 124. Since the high-side MOSFET 121, the low-side MOSFET 122, and the decoupling MOSFET 123 are all N-channel MOSFETs, power consumption is low even when the high-side MOSFET 121, the low-side MOSFET 122, and the decoupling MOSFET 123 are all set in an electrically conductive state in the heating mode.

Therefore, the sensor device 100 having a low power consumption can be provided. Moreover, since the high-side MOSFET 121, the low-side MOSFET 122, and the decoupling MOSFET 123 are all N-channel MOSFETs, production is facilitated, and electrical reliability can be improved with reduced unevenness between products. In addition, the product cost can be reduced.

The capacitor 134 for DC separation may further be provided between the sensor electrode 110 and the electrostatic detection circuit 130. This makes it possible to detect the capacitance of the sensor electrode 110 accurately by separating the electrostatic detection circuit 130 from a DC signal.

The voltage regulator 126 may be a constant voltage regulator that outputs a voltage V3 that is higher than the voltage V1 of the power source 51. This makes it possible to make the voltage V3 high without being constrained by the voltage V1 of the power source 51, and to thereby reduce the parasitic capacitances Coss between the drain and the source of the low-side MOSFET 122 and the decoupling MOSFET 123 and reduce the parasitic capacitance Crgl of the sensor electrode 110. As a result, the electrostatic detection sensitivity is improved.

The source of the high-side MOSFET 121 and the source of the decoupling MOSFET 123 are connected to the reference potential point via the switch (124), and the switch may be an N-channel type MOSFET of which the drain is connected to the source of the high-side MOSFET 121 and the source of the decoupling MOSFET 123, and of which the source is connected to the reference potential point. The switch (124) being an N-channel type MOSFET can further facilitate production, and further improve the electrical reliability by further reducing unevenness between products. Moreover, manufacturing cost can be reduced.

The source of the high-side MOSFET 121 and the source of the decoupling MOSFET 123 are connected to the reference potential point via the resistor (124), and the resistance value of the resistor is preferably 1 kΩ to 100 kΩ. This makes it possible to inhibit a current to flow from the connection point 123A to the reference potential point in the heating mode, and to reliably maintain the connection point 123A at the reference potential in the non-heating mode. Moreover, the configuration is very simple, and electrical reliability can be improved and product cost can be reduced.

The electrostatic detection circuit 130 may detect the capacitance by the self-capacitance method. The sensitivity of the capacitance at the sensor electrode 110 can be improved.

Further, the control circuit 140 may control the high-side MOSFET 121, the low-side MOSFET 122, and the decoupling MOSFET 123 to enter an electrically conductive state when supplying the power for heating from the power source 51 to the sensor electrode 110, and may control the high-side MOSFET 121 and the decoupling MOSFET 123 to enter an open state and subsequently control the low-side MOSFET 122 to enter an open state when stopping supply of the power for heating from the power source 51 to the sensor electrode 110. By switching the high-side MOSFET 121, the low-side MOSFET 122, and the decoupling MOSFET 123 between the electrically conductive state and the open state, it is possible to realize the circuit for the heating mode and the circuit for the non-heating mode easily. In addition, when stopping supply of the power for heating from the power source 51 to the sensor electrode 110, by switching the circuit OFF from a side closer to the power source 51, it is possible to improve safety.

The electronic element may be a switch (124). The control circuit 140 controls the switch (124) to enter an open state when supplying the power for heating from the power source 51 to the sensor electrode 110, and controls the high-side MOSFET 121 and the decoupling MOSFET 123 to enter an open state and controls the switch to enter an electrically conductive state, and subsequently controls the low-side switch to enter an open state when stopping supply of the power for heating from the power source 51 to the sensor electrode 110. By switching the high-side MOSFET 121, the low-side MOSFET 122, and the decoupling MOSFET 123 between the electrically conductive state and the open state, it is possible to realize the circuit for the heating mode and the circuit for the non-heating mode easily. By switching the high-side MOSFET 121, the low-side MOSFET 122, and the decoupling MOSFET 123, and the switch (124) between the electrically conductive state and the open state, it is possible to realize the circuit for the heating mode and the circuit for the non-heating mode easily. When stopping supply of the power for heating from the power source 51 to the sensor electrode 110, by switching OFF the circuit from a side closer to the power source 51, it is possible to improve safety.

The electronic element may be a resistor (124). The electronic element can be realized with a simple configuration.

### Modified Example of Embodiment

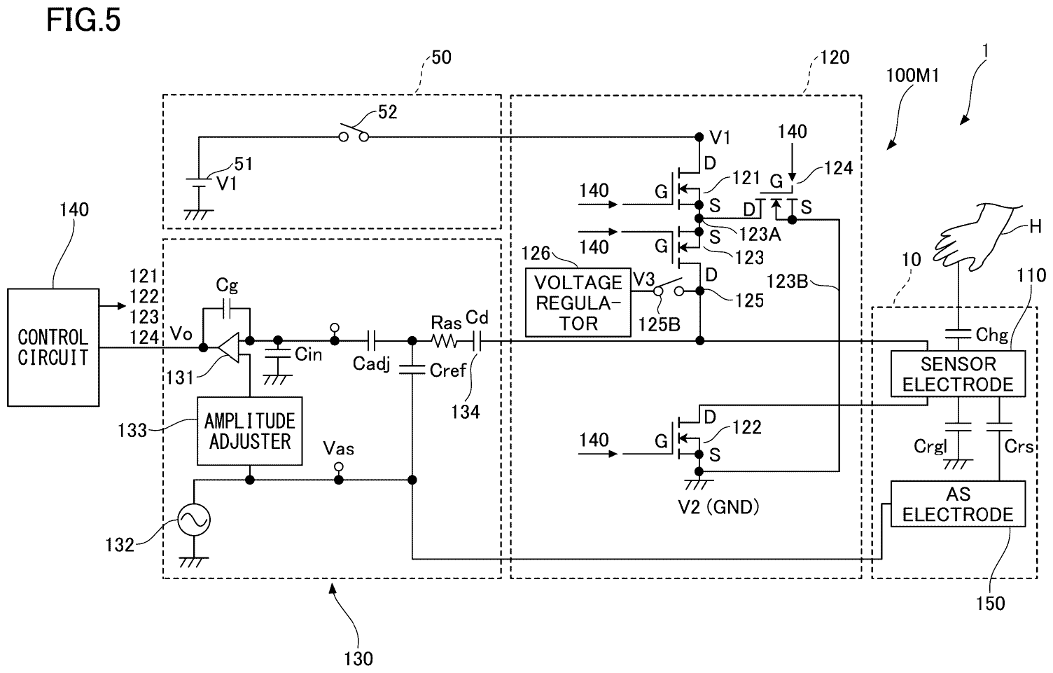

FIG. 5 is a diagram showing an example of the circuit configuration of a sensor device 100M1 according to a modified example of the embodiment. FIG. 5 also shows the power source circuit 50 of the vehicle 1 on which the sensor device 100M1 is mounted.

The sensor device 100M1 has a configuration including an active shield electrode 150 in addition to the sensor device 100 shown in FIG. 2. Moreover, a switch 125B may be provided between the voltage regulator 126 and the node 125 in order to prevent a backflow to the voltage regulator 126. The switch 125B is provided instead of the diode 125A shown in FIG. 2. The other particulars are the same as those in the sensor device 100 shown in FIG. 2.

The active shield electrode 150 is positioned near the sensor electrode 110 on the back side of the sensor electrode 110. The back side of the sensor electrode 110 means the side opposite to the side where the hand H approaches the sensor electrode 110. Near the sensor electrode 110 means that the sensor electrode 110 and the active shield electrode 150 are close enough to be capacitively coupled. The capacitance between the sensor electrode 110 and the active shield electrode 150 is referred to as Crs.

The active shield electrode 150 is connected to the AC signal source 132 and is driven by a signal containing an AC component having the same frequency and phase as those of an AC component contained in a signal supplied to the sensor electrode 110. The amplitude of the AC component of the signal supplied to the active shield electrode 150 is greater than the amplitude of the AC component of the signal supplied to the sensor electrode 110.

The active shield electrode 150 is provided to shield the sensor electrode 110 from noise and to inhibit the effect of parasitic capacitance. The active shield electrode 150 is positioned near the sensor electrode 110 with a predetermined gap so as to be able to shield the sensor electrode 110 from noise from the reference potential point such as the ground or the like and to be able to inhibit the effect of parasitic capacitance between the sensor electrode and the reference potential point.

The amplitude adjuster 133 performs adjustment as to offset a current flowing from the active shield electrode 150 to the sensor electrode 110 through the capacitance Crs and a current flowing from the sensor electrode 110 to the reference potential point through the parasitic capacitor Crgl by each other. That is, the amplitude is adjusted such that the drive current flowing to the sensor electrode 110 becomes zero in a state in which there is no hand H, which is an object, that is close to the sensor electrode 110 (in a state in which the capacitance Chg is 0).

Since the sensor device 100M1 of the modified embodiment further includes the active shield electrode 150 positioned near the sensor electrode 110, it is possible to reduce the impact of noise and parasitic capacitance on the sensor electrode 110 and to also reduce the impact of noise and parasitic capacitance on the wirings or the like included in the electrostatic detection circuit 130 by the active shield electrode 150.

Although the sensor device of an illustrative embodiment of the present disclosure has been described above, the present disclosure is not limited to the specifically disclosed embodiment, and various modifications and changes are applicable without departing from the scope of the claims.

With respect to the above embodiment, the following Appendices are further disclosed.

### Appendix 1

A sensor device, including:
a sensor electrode operable as a heating element;
an electrostatic detection circuit configured to detect a capacitance between the sensor electrode and an object;
a high-side switch connected to a power source for supplying power for heating to the sensor electrode;
a decoupling switch provided between the high-side switch and one end of the sensor electrode;
a low-side switch provided between the other end of the sensor electrode and a reference potential point;
a voltage supply circuit configured to supply a voltage to a node between the decoupling switch and the one end of the sensor electrode such that the voltage of the node becomes higher than a voltage of the reference potential point;
an electronic element composed of a resistor or a switch provided between a connection point between the high-side switch and the decoupling switch and the reference potential point; and
a controller configured to control the high-side switch, the decoupling switch, and the low-side switch,
wherein a voltage of the power source is higher than the voltage of the reference potential point,
wherein the high-side switch, the decoupling switch, and the low-side switch are N-channel MOSFETs,
wherein a drain of the high-side switch is connected to the power source,
wherein a drain of the decoupling switch is connected to the node,
wherein a drain of the low-side switch is connected to the other end of the sensor electrode,
wherein a source of the low-side switch is connected to the reference potential point, and
wherein a source of the high-side switch and a source of the decoupling switch are connected to the connection point and are connected to the reference potential point via the electronic element.

### Appendix 2

The sensor device according to Appendix 1, further including:
a capacitor for direct-current separation provided between the sensor electrode and the electrostatic detection circuit.

### Appendix 3

The sensor device according to Appendix 1 or 2,
wherein the voltage supply circuit is a constant voltage regulator configured to output the voltage that is higher than the voltage of the power source.

### Appendix 4

The sensor device according to any one of Appendices 1 to 3,
wherein the source of the high-side switch and the source of the decoupling switch are connected to the reference potential point via the switch, and
the switch is an N-channel MOSFET having a drain that is connected to the source of the high-side switch and the source of the decoupling switch, and a source that is connected to the reference potential point.

### Appendix 5

The sensor device according to any one of Appendices 1 to 3,
wherein the source of the high-side switch and the source of the decoupling switch are connected to the reference potential point via the resistor, and
a resistance value of the resistor is higher than 1 kΩ and lower than 100 kΩ.

### Appendix 6

The sensor device according to any one of Appendices 1 to 5,
wherein the electrostatic detection circuit detects the capacitance by a self-capacitance method.

### Appendix 7

The sensor device according to any one of Appendices 1 to 6, further including:
an active shield electrode positioned near the sensor electrode.

### Appendix 8

The sensor device according to any one of Appendices 1 to 7,
wherein when supplying the power for heating from the power source to the sensor electrode, the controller controls the high-side switch, the low-side switch, and the decoupling switch to enter an electrically conductive state, and
when stopping supply of the power for heating from the power source to the sensor electrode, the controller controls the high-side switch and the decoupling switch to enter an open state, and subsequently controls the low-side switch to enter an open state.

### Appendix 9

The sensor device according to any one of Appendices 1 to 7,
wherein the electronic element is the switch, and
wherein when supplying the power for heating from the power source to the sensor electrode, the controller controls the switch to enter an open state, and
when stopping supply of the power for heating from the power source to the sensor electrode, the controller controls the high-side switch and the decoupling switch to enter an open state and controls the switch to enter an electrically conductive state, and subsequently controls the low-side switch to enter an open state.

### Appendix 10

The sensor device according to any one of Appendices 1 to 8,
wherein the electronic element is the resistor.

What is claimed is:

1. A sensor device, comprising:
a sensor electrode operable as a heating element;
an electrostatic detection circuit configured to detect a capacitance between the sensor electrode and an object;
a high-side switch connected to a power source for supplying power for heating to the sensor electrode;
a decoupling switch provided between the high-side switch and one end of the sensor electrode;
a low-side switch provided between the other end of the sensor electrode and a reference potential point;
a voltage supply circuit configured to supply a voltage to a node between the decoupling switch and the one end of the sensor electrode such that the voltage of the node becomes higher than a voltage of the reference potential point;
an electronic element composed of a resistor or a switch provided between a connection point between the high-side switch and the decoupling switch and the reference potential point; and
a controller configured to control the high-side switch, the decoupling switch, and the low-side switch,
wherein a voltage of the power source is higher than the voltage of the reference potential point,
wherein the high-side switch, the decoupling switch, and the low-side switch are N-channel MOSFETs,
wherein a drain of the high-side switch is connected to the power source,
wherein a drain of the decoupling switch is connected to the node,
wherein a drain of the low-side switch is connected to the other end of the sensor electrode,
wherein a source of the low-side switch is connected to the reference potential point, and
wherein a source of the high-side switch and a source of the decoupling switch are connected to the connection point and are connected to the reference potential point via the electronic element.

2. The sensor device according to claim 1, further comprising:
a capacitor for direct-current separation provided between the sensor electrode and the electrostatic detection circuit.

3. The sensor device according to claim 1,
wherein the voltage supply circuit is a constant voltage regulator configured to output a voltage that is higher than the voltage of the power source.

4. The sensor device according to claim 1,
wherein the source of the high-side switch and the source of the decoupling switch are connected to the reference potential point via the switch, and
the switch is an N-channel MOSFET having a drain that is connected to the source of the high-side switch and the source of the decoupling switch, and a source that is connected to the reference potential point.

5. The sensor device according to claim 1,
wherein the source of the high-side switch and the source of the decoupling switch are connected to the reference potential point via the resistor, and
a resistance value of the resistor is higher than 1 kΩ and lower than 100 kΩ.

6. The sensor device according to claim 1,
wherein the electrostatic detection circuit detects the capacitance by a self-capacitance method.

7. The sensor device according to claim 1, further comprising:
an active shield electrode positioned near the sensor electrode.

8. The sensor device according to claim 1,
wherein when supplying the power for heating from the power source to the sensor electrode, the controller controls the high-side switch, the low-side switch, and the decoupling switch to enter an electrically conductive state, and
when stopping supply of the power for heating from the power source to the sensor electrode, the controller controls the high-side switch and the decoupling switch to enter an open state and subsequently controls the low-side switch to enter an open state.

9. The sensor device according to claim 1,
wherein the electronic element is the switch, and
wherein when supplying the power for heating from the power source to the sensor electrode, the controller controls the switch to enter an open state, and
when stopping supply of the power for heating from the power source to the sensor electrode, the controller controls the high-side switch and the decoupling switch to enter an open state and controls the switch to enter an electrically conductive state, and subsequently controls the low-side switch to enter an open state.

10. The sensor device according to claim 1,
wherein the electronic element is the resistor.
